(19) United States
(12) Patent Application Publication
(10) Pub. No.: US 2026/0255637 A1
(43) Pub. Date: Aug. 27, 2026

(54) FERROELECTRIC THIN FILM TRANSISTOR AND METHOD OF MANUFACTURING THE SAME

(71) Applicant: UNIVERSITY-INDUSTRY COOPERATION GROUP OF KYUNG HEE UNIVERSITY, Yongin-si (KR)

(72) Inventors: Jin JANG, Seoul (KR); Heon Bang LEE, Seoul (KR)

(73) Assignee: UNIVERSITY-INDUSTRY COOPERATION GROUP OF KYUNG HEE UNIVERSITY, Yongin-si (KR)

(21) Appl. No.: 19/277,786

(22) Filed: Jul. 23, 2025

(30) Foreign Application Priority Data
Feb. 21, 2025 (KR) 10-2025-0022664

(51) Int. Cl. H10D 30/69; H10D 30/01; H10D 30/67

(52) U.S. Cl. CPC H10D 30/701; H10D 30/0312; H10D 30/0415; H10D 30/6755

(57) ABSTRACT

The present invention relates to a ferroelectric thin film transistor and a method of manufacturing the same. According to an example embodiment of the present invention, a ferroelectric thin film transistor may include: a ferroelectric layer formed by depositing a ferroelectric material on a buffer layer provided on a substrate, a semiconductor layer formed by depositing an oxide on the ferroelectric layer and doping an upper region thereof through plasma treatment, a gate insulating layer formed by depositing a dielectric material on the semiconductor layer, a gate electrode formed by depositing a metal material on the gate insulating layer and performing a gate patterning process, an interlayer formed on the gate electrode and the semiconductor layer, and a source electrode and a drain electrode formed by patterning the interlayer and depositing a metal material.

### CROSS-REFERENCE TO RELATED APPLICATION

This application claims priority from and the benefit of Korean Patent Application No. 10-2025-0022664 filed on Feb. 21, 2025, in the Korean Intellectual Property Office, the disclosure of which is incorporated herein by reference.

### BACKGROUND OF THE DISCLOSURE

### Field of the Disclosure

Example embodiments relate to a ferroelectric thin film transistor and a method of manufacturing the same, and more particularly, to a manufacturing technique of a ferroelectric thin film transistor having a metal-insulator-semiconductor-ferroelectric (MISF) structure in which a semiconductor layer is formed on a ferroelectric layer, and which has a self-aligned (SA) and coplanar structure.

### Description of the Related Art

Ferroelectric devices are attracting increasing attention across a wide range of applications, including memory, energy, neuromorphic systems, and displays, influencing various aspects of human life.

Research on ferroelectric materials has focused on the ferroelectric properties of fluorite-structured thin films derived from non-centrosymmetric orthorhombic crystal systems.

These materials offer several advantages, including environmental friendliness, a wide bandgap, and a simplified structure.

Zirconium oxide (ZrO2)-based thin films, in particular, have received considerable attention due to their ferroelectric characteristics over a wide thickness range.

Compared to hafnium zirconium oxide (HZO), ZrO₂ films exhibit a lower crystallization temperature, which improves compatibility with complementary metal-oxide-semiconductor (CMOS) processes, making them practically applicable across various technological domains.

Ferroelectric stacks have garnered attention for their high-k properties that enable low-voltage operation.

However, such characteristics may easily cause breakdowns that limit the operating voltage of ferroelectric field-effect transistors (FeFETs).

Given that ferroelectricity is closely linked to crystallinity, high leakage current may become a critical issue.

Oxygen vacancy aggregation during the crystallization process may increase leakage current and lead to device failure.

This may also limit the memory window (MW), making FeFETs more susceptible to noise and challenging their applicability in circuit integration.

Although recent studies have focused on increasing the MW while maintaining operational stability, they often require complex structures such as floating gates, capping layers, seed layers, or electron trap layers.

However, adding such extra layers may introduce several drawbacks.

For example, additional layers may reduce ferroelectricity, and conductive layers may increase the risk of dielectric breakdown.

Furthermore, an increased number of layers leads to more complex fabrication processes.

Due to these factors, there is growing interest in simpler transistor structures that may support large memory capacity while maintaining stable operation.

Compatibility with conventional switching transistors in terms of fabrication processes is also important from the perspective of circuit-level integration.

Most studies adopt relatively complex structures in which ferroelectric capacitors or transistors are fabricated on top of CMOS devices.

However, this limits the annealing temperature of ferroelectric layers, even though high-temperature annealing is necessary for complete crystallization of the ferroelectric layer.

Among deposition methods, chemical solution deposition (CSD) has recently been explored as an alternative to atomic layer deposition (ALD) for depositing fluorite-structured thin films.

Compared to thin films deposited by ALD, those fabricated via CSD exhibit ferroelectric behavior in thicker films and may be more suitable for piezoelectric or pyroelectric applications.

Ferroelectricity has been observed even in 1 μm-thick La:HfO₂, and CSD-based ferroelectric films have highly uniform particle sizes in the range of 5 to 10 nm, which are generally smaller than those of ALD-based films.

The smaller particle size helps effectively suppress the non-ferroelectric monoclinic phase (m-phase), thereby enhancing ferroelectric performance indicators such as remnant polarization (Pᵣ) and coercive voltage (Vc), and expanding process margins.

Solution-based deposition via spray pyrolysis offers high process feasibility due to its low cost and suitability for large-area manufacturing.

However, solution-processed films typically require higher annealing temperatures because of residual organic and inorganic materials resulting from incomplete thermal decomposition of the precursor.

High-temperature annealing, in turn, may cause undesirable diffusion or chemical reactions with adjacent layers.

This may degrade ferroelectricity due to oxygen vacancy formation and further restrict both the temperature and duration of annealing, thereby narrowing the process window for forming a stable ferroelectric phase.

### SUMMARY

An objective of example embodiments is to provide a ferroelectric thin film transistor and a method of manufacturing the same, in which a semiconductor layer is formed on a ferroelectric layer to realize a metal-insulator-semiconductor-ferroelectric (MISF) structure, and the transistor has a self-aligned (SA) and coplanar configuration.

Another objective of example embodiments is to provide a method of manufacturing a ferroelectric thin film transistor by placing a ferroelectric layer below a semiconductor layer and performing annealing without introducing additional interfaces for stacking other layers.

Still another objective of example embodiments is to fabricate a ferroelectric thin film transistor by incorporating a ferroelectric layer below the semiconductor layer through an oxide thin-film transistor (TFT) process, wherein the ferroelectric layer is located on a substrate to minimize process-induced effects on the semiconductor layer.

Yet another objective of example embodiments is to provide a ferroelectric thin film transistor and a method of manufacturing the same, in which an Ar/O2 plasma process is applied while a ferroelectric layer is disposed below the semiconductor layer, thereby reducing the Vo (oxygen vacancy) effect, improving durability, and exhibiting hysteresis behavior with stable performance across temperature variations.

According to an example embodiment, a ferroelectric thin film transistor may include: a ferroelectric layer formed by depositing a ferroelectric material on a buffer layer provided on a substrate, a semiconductor layer formed by depositing an oxide on the ferroelectric layer and doping an upper region thereof through plasma treatment, a gate insulating layer formed by depositing a dielectric material on the semiconductor layer, a gate electrode formed by depositing a metal material on the gate insulating layer and performing a gate patterning process, an interlayer formed on the gate electrode and the semiconductor layer, and a source electrode and a drain electrode formed by patterning the interlayer and depositing a metal material.

The ferroelectric layer may be located below the semiconductor layer and may exhibit a polarity based on ferroelectricity of the ferroelectric material.

The semiconductor layer may determine whether a channel is formed in an ON state or an OFF state based on a gate voltage applied through the gate electrode and the polarity.

The ferroelectric material may comprise ZrO2, the oxide may comprise indium gallium zinc oxide (IGZO), the metal material may comprise Mo, and the dielectric material may comprise SiO₂.

The stacked structure of the ferroelectric layer and the semiconductor layer may include a uniform distribution of In and Ga based on the IGZO and Zr and O based on the ZrO₂.

The semiconductor layer may be determined to be in an OFF state when: the gate voltage is less than a forward threshold voltage and the polarity is negative, the gate voltage is less than or equal to a backward threshold voltage and the polarity transitions between the negative polarity and a positive polarity, or the gate voltage is less than the backward threshold voltage and the polarity is negative.

The semiconductor layer may be determined to be in an ON state when: the gate voltage is greater than or equal to a forward threshold voltage and the polarity transitions between a negative polarity and a positive polarity, or the gate voltage exceeds the forward threshold voltage and the polarity is positive.

According to another example embodiment, a method of manufacturing a ferroelectric thin film transistor may include: forming a ferroelectric layer by depositing a ferroelectric material on a buffer layer provided on a substrate, forming a semiconductor layer by depositing an oxide on the ferroelectric layer, forming a gate insulating layer by depositing a dielectric material on the semiconductor layer, forming a gate electrode by depositing a metal material on the gate insulating layer and performing a gate patterning process, forming a doped semiconductor layer by doping an upper region of the semiconductor layer through plasma treatment, forming an interlayer on the gate electrode and the doped semiconductor layer, and forming a source electrode and a drain electrode by patterning the interlayer and depositing a metal material.

The step of forming the ferroelectric layer may include: depositing the ferroelectric material as the ferroelectric layer by spray pyrolysis of a precursor solution containing the ferroelectric material, and forming a crystallized ferroelectric layer by performing plasma treatment using a plasma gas on the deposited ferroelectric layer and annealing the layer in a nitrogen (N₂) atmosphere.

The ferroelectric material may comprise ZrO₂, the oxide may comprise indium gallium zinc oxide (IGZO), the metal material may comprise Mo, and the dielectric material may comprise SiO₂.

The stacked structure of the ferroelectric layer and the semiconductor layer may include a uniform distribution of In and Ga based on the IGZO and Zr and O based on the ZrO₂.

The step of forming the doped semiconductor layer may include: forming the doped semiconductor layer such that an n⁺ doping region is included in the upper region by performing a self-aligned (SA) process for n⁺ contacts through NF3 plasma treatment that introduces fluorine (F) to a predetermined depth.

The semiconductor layer may be determined to be in an OFF state when: the gate voltage is less than a forward threshold voltage and the polarity is negative, the gate voltage is less than or equal to a backward threshold voltage and the polarity transitions between the negative polarity and a positive polarity, or the gate voltage is less than the backward threshold voltage and the polarity is negative.

The semiconductor layer may be determined to be in an ON state when: the gate voltage is greater than or equal to a forward threshold voltage and the polarity transitions between a negative polarity and a positive polarity, or the gate voltage exceeds the forward threshold voltage and the polarity is positive.

The present invention may provide a ferroelectric thin film transistor and a method of manufacturing the same, in which a semiconductor layer is formed on a ferroelectric layer to realize a metal-insulator-semiconductor-ferroelectric (MISF) structure, and the transistor has a self-aligned (SA) and coplanar configuration.

The present invention may further provide a method of manufacturing a ferroelectric thin film transistor by placing a ferroelectric layer below a semiconductor layer and performing annealing without introducing additional interfaces required for stacking other layers.

The present invention may enable fabrication of a ferroelectric thin film transistor by incorporating a ferroelectric layer below the semiconductor layer through an oxide thin-film transistor (TFT) process, wherein the ferroelectric layer is positioned on a substrate to minimize process-induced effects on the semiconductor layer.

The present invention may also provide a ferroelectric thin film transistor and a method of manufacturing the same, in which an Ar/O₂ plasma process is performed while the ferroelectric layer is disposed below the semiconductor layer, thereby reducing the Vo (oxygen vacancy) effect, improving durability, and exhibiting stable performance across temperature variations along with hysteresis behavior.

### BRIEF DESCRIPTION OF DRAWINGS

Embodiments will be described in more detail with regard to the drawings, wherein like reference numerals refer to like parts throughout the various drawings unless otherwise specified, and wherein:

FIGS. 1A and 1B are diagrams illustrating the structure of a ferroelectric thin film transistor according to an example embodiment of the present invention.

FIGS. 2 and 3 are diagrams illustrating a method of manufacturing a ferroelectric thin film transistor according to an example embodiment of the present invention.

FIGS. 4A to 5C are diagrams illustrating the stacked structure of a ferroelectric thin film transistor according to an example embodiment of the present invention.

FIGS. 6A and 6B are diagrams illustrating the ferroelectric properties of a ferroelectric thin film transistor according to an example embodiment of the present invention.

FIGS. 7A to 7C are diagrams illustrating hysteresis curves of a ferroelectric thin film transistor according to an example embodiment of the present invention.

FIGS. 8A and 8B are diagrams illustrating the stability of a ferroelectric thin film transistor according to an example embodiment of the present invention.

FIGS. 9 to 10B are diagrams illustrating the process compatibility of a ferroelectric thin film transistor according to an example embodiment of the present invention.

FIGS. 11A and 11B are diagrams illustrating the operation of a ferroelectric thin film transistor according to an example embodiment of the present invention.

### DETAILED DESCRIPTION OF THE DISCLOSURE

Hereinafter, various example embodiments of the present disclosure will be described with reference to the accompanying drawings.

The example embodiments and the terminology used therein are not intended to limit the scope of the disclosed technology to specific implementations, but should be understood to include various modifications, equivalents, and/or alternatives.

In the following description of the various example embodiments, detailed descriptions of well-known functions or structures may be omitted if such details are deemed to unnecessarily obscure the essence of the invention.

Terms defined below are intended to describe functions within the various embodiments, and may differ depending on user, operator, or customary usage. Therefore, the definitions should be interpreted based on the overall content of this specification.

In the drawings, similar reference numerals may be used for similar components.

Unless clearly stated otherwise in context, singular expressions may include plural meanings as well.

Expressions such as “A or B” or “at least one of A and/or B” are intended to encompass all possible combinations of the listed elements.

Terms such as “first,” “second,” “primary,” or “secondary” may be used to distinguish between elements, regardless of their order or importance, and should not be interpreted as limiting the elements.

When a certain (e.g., first) component is described as being “connected to” or “coupled to” another (e.g., second) component, this may mean that the component is directly connected or coupled, or indirectly connected or coupled through another (e.g., third) component.

In this specification, the phrase “configured to” may be used interchangeably with expressions such as “adapted to,” “capable of,” “designed to,” “intended to,” or “set to,” depending on the context, whether implemented in hardware, software, or a combination thereof.

In some cases, an expression like “a device configured to perform A, B, and C” may refer to a dedicated processor (e.g., embedded processor), or a general-purpose processor (e.g., CPU or application processor) that is capable of performing such operations by executing one or more software programs stored in a memory device.

Unless otherwise specified or clearly contradicted by context, the term “or” is used in an inclusive sense rather than an exclusive sense.

For example, the phrase “X uses A or B” is intended to encompass all natural inclusive permutations unless explicitly stated otherwise.

As used herein, terms ending in “-unit,” “-module,” or “-processor” refer to elements that perform at least one function or operation and may be implemented in hardware, software, or a combination of both.

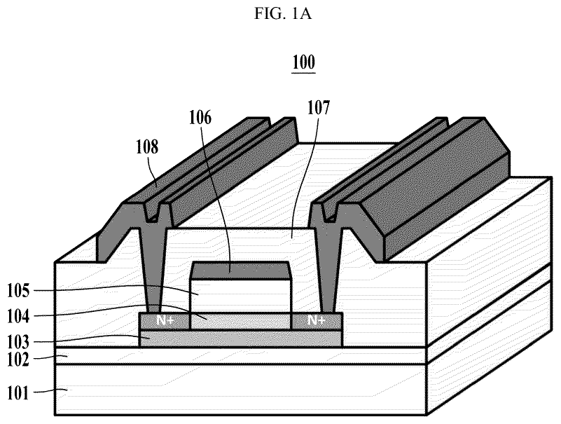

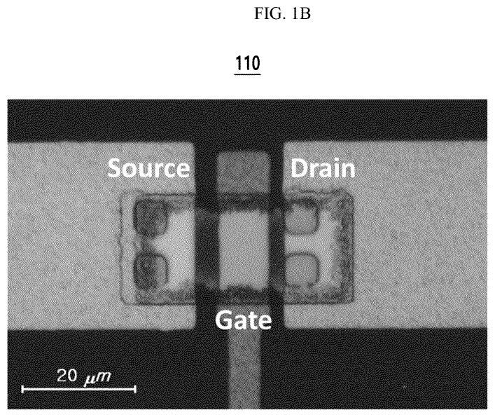

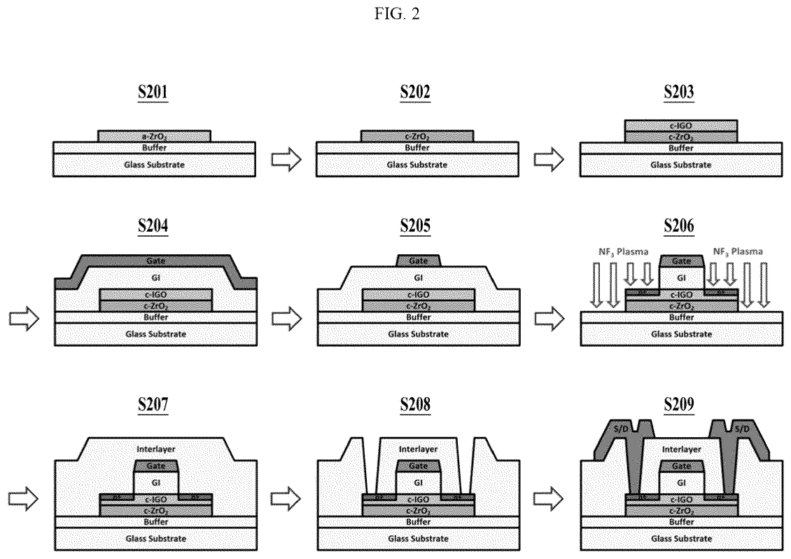

FIGS. 1A and 1B are diagrams illustrating the structure of a ferroelectric thin film transistor according to an example embodiment of the present invention.

FIG. 1A illustrates the configuration and structure of a ferroelectric thin film transistor according to an example embodiment of the present invention.

Referring to FIG. 1A, a ferroelectric thin film transistor 100 according to an example embodiment of the present invention may include a substrate 101, a buffer layer 102, a ferroelectric layer 103, a semiconductor layer 104, a gate insulating layer 105, a gate electrode 106, an interlayer 107, and source/drain electrodes 108.

The ferroelectric layer 103 may be formed by depositing a ferroelectric material on the buffer layer 102, which is provided on the substrate 101.

The semiconductor layer 104 may be formed by depositing an oxide on the ferroelectric layer and doping an upper region thereof through plasma treatment.

The semiconductor layer 104 may be doped to an N⁺ level through plasma treatment.

The gate insulating layer 105 may be formed by depositing a dielectric material on the semiconductor layer 104.

The gate electrode 106 may be formed by depositing a metal material on the gate insulating layer 105 and performing a gate patterning process.

The interlayer 107 may be formed on the gate electrode 106 and the semiconductor layer 104.

The source and drain electrodes 108 may be formed by patterning the interlayer 107 and depositing a metal material.

The ferroelectric layer 103 may be located below the semiconductor layer 104 and may exhibit a polarity based on the ferroelectricity of the ferroelectric material.

The semiconductor layer 104 may determine whether a channel is formed in an ON state or an OFF state based on a gate voltage applied through the gate electrode 106 and the polarity.

For example, the ferroelectric material may comprise ZrO₂, the oxide may comprise indium gallium zinc oxide (IGZO), the metal material may comprise Mo, and the dielectric material may comprise SiO₂.

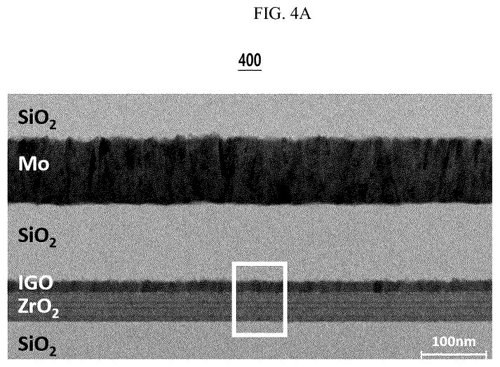

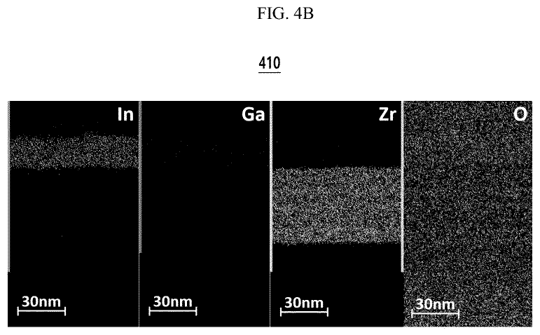

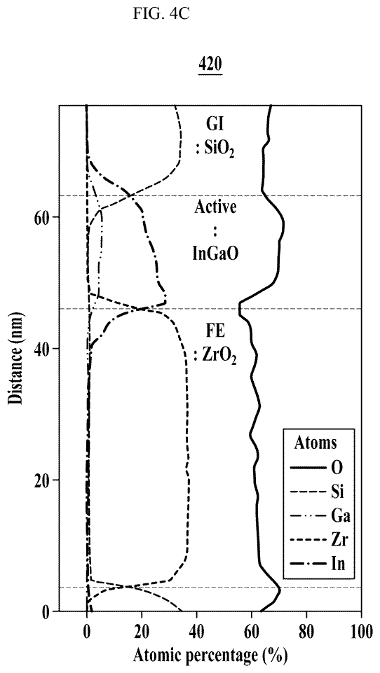

According to an example embodiment of the present invention, the stacked structure of the ferroelectric layer 103 and the semiconductor layer 104 may include a uniform distribution of In and Ga based on the IGZO, and Zr and O based on the ZrO₂. This stacked structure is further illustrated with reference to FIGS. 4A to 4C.

The semiconductor layer 104 may cause the ferroelectric thin film transistor 100 to be in an OFF state when the gate voltage is less than a forward threshold voltage and the polarity of the ferroelectric layer 103 is negative.

The semiconductor layer 104 may also cause the ferroelectric thin film transistor 100 to be in an OFF state when the gate voltage is less than or equal to a backward threshold voltage and the polarity of the ferroelectric layer 103 transitions between a negative polarity and a positive polarity.

The semiconductor layer 104 may further cause the ferroelectric thin film transistor 100 to be in an OFF state when the gate voltage is less than the backward threshold voltage and the polarity of the ferroelectric layer 103 is negative.

The semiconductor layer 104 may be determined to be in an ON state when the gate voltage is greater than or equal to a forward threshold voltage and the polarity of the ferroelectric layer 103 transitions between a negative polarity and a positive polarity.

Furthermore, when the gate voltage exceeds the forward threshold voltage and the polarity of the ferroelectric layer 103 is positive, the ferroelectric thin film transistor 100 may be determined to be in an ON state.

FIG. 1B illustrates an optical image related to the structure of a ferroelectric thin film transistor according to an example embodiment of the present invention.

Referring to FIG. 1B, the optical image 110 of the ferroelectric thin film transistor according to an example embodiment of the present invention was fabricated with a W/L of 20 μm/8.9 μm.

The optical image 110 shows a top view of the ferroelectric thin film transistor.

The ferroelectric thin film transistor includes a metal layer, an insulating layer, a semiconductor layer, and a ferroelectric layer.

In the ferroelectric thin film transistor according to an example embodiment of the present invention, although the overlap area between the gate electrode and the source/drain electrodes is relatively large, the resulting capacitance is negligibly small.

The ferroelectric thin film transistor according to an example embodiment of the present invention has a metal-insulator-semiconductor-ferroelectric (MISF) structure.

Accordingly, the present invention may provide a ferroelectric thin film transistor and a method of manufacturing the same, in which a semiconductor layer is formed on a ferroelectric layer to realize a MISF structure, and the transistor has a self-aligned (SA) and coplanar configuration.

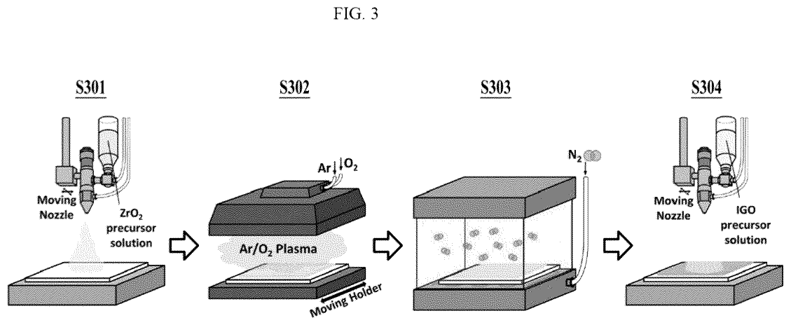

FIGS. 2 and 3 are diagrams illustrating a method of manufacturing a ferroelectric thin film transistor according to an example embodiment of the present invention.

FIG. 2 illustrates a method of manufacturing a ferroelectric thin film transistor according to an example embodiment of the present invention.

Referring to FIG. 2, in step S201, the method of manufacturing a ferroelectric thin film transistor according to an example embodiment of the present invention includes forming a ferroelectric layer by depositing a ferroelectric material on a buffer layer provided on a substrate.

The method includes depositing ZrO₂ by spray pyrolysis followed by patterning at 370° C.

In other words, in the method of manufacturing a ferroelectric thin film transistor, a precursor solution containing a ferroelectric material is deposited as the ferroelectric layer by spray pyrolysis.

In step S202, the method of manufacturing a ferroelectric thin film transistor according to an example embodiment of the present invention further includes performing plasma treatment and annealing on the ferroelectric layer.

According to an example embodiment of the present invention, the method of manufacturing a ferroelectric thin film transistor includes performing plasma treatment on the deposited ferroelectric layer using a plasma gas, followed by annealing in a nitrogen (N₂) atmosphere to form a crystallized ferroelectric layer.

In step S203, the method includes forming a semiconductor layer by depositing an oxide on the ferroelectric layer.

More specifically, the semiconductor layer may be formed by depositing c-InGaO grown by spray pyrolysis at 390° C.

In step S204, the method includes depositing a dielectric material on the semiconductor layer and subsequently depositing a metal material.

For example, the dielectric material may be deposited by plasma-enhanced chemical vapor deposition (PECVD), and the metal material may be deposited by DC sputtering.

In step S205, the method includes forming a gate insulating layer and a gate electrode by depositing a metal material on the gate insulating layer and performing gate patterning.

In step S206, the method includes doping the semiconductor layer by performing a self-aligned process and plasma doping.

That is, the doped semiconductor layer may be formed by performing a self-aligned (SA) process for n⁺ contacts, wherein fluorine (F) is introduced to a predetermined depth through NF₃ plasma treatment, thereby forming an n⁺ doping region in the upper region of the semiconductor layer.

In step S207, the method includes forming an interlayer on the gate electrode and the semiconductor layer.

In step S208, the method includes patterning the interlayer using PECVD to form a space for source and drain electrode formation.

In step S209, the method includes forming a source electrode and a drain electrode by patterning the interlayer and depositing a metal material.

The ferroelectric thin film transistor according to an example embodiment of the present invention exhibits ferroelectricity based on the ferroelectric layer located below the semiconductor layer.

The transistor may express a polarity based on ferroelectricity, including a negative polarity, a positive polarity, and an intermediate polarity transitioning from negative to positive or from positive to negative.

Accordingly, the present invention may provide a method of manufacturing a ferroelectric thin film transistor by placing a ferroelectric layer below a semiconductor layer and performing annealing without the need for additional interfaces for stacking other layers.

FIG. 3 is a diagram illustrating a method of manufacturing a ferroelectric thin film transistor according to an example embodiment of the present invention.

FIG. 3 further illustrates, in connection with the method of manufacturing a ferroelectric thin film transistor according to an example embodiment of the present invention, the process for forming the ferroelectric layer and the semiconductor layer.

Referring to FIG. 3, in step S301, the method of manufacturing a ferroelectric thin film transistor includes forming a ferroelectric ZrO₂ layer by spray pyrolysis of a precursor solution at 370° C. with a flow rate of 3.0 mL/min and a spray nozzle scan speed of 7.0 cm/s.

During deposition, the spray nozzle is positioned 10 cm above the substrate.

Spray pyrolysis is performed for four cycles to achieve a film thickness of approximately 40 nm.

In step S302, the method includes performing Ar/O₂ plasma treatment to reduce surface defects of the deposited ferroelectric layer and improve the stability of the device.

In step S303, the method includes performing thermal annealing at 550° C. in a nitrogen (N₂) ambient to crystallize the ferroelectric layer.

Then, in step S304, the method includes growing crystalline indium gallium oxide (InGaO) at 390° C. via spray pyrolysis without additional annealing.

According to an example embodiment of the present invention, the method of manufacturing a ferroelectric thin film transistor includes setting the flow rate to 1.0 mL/min, and maintaining the spray nozzle scan speed and height equal to the conditions used for ZrO2 deposition.

The method includes performing a total of four spray cycles to achieve a film thickness of 20 nm, and treating the InGaO layer with N₂O plasma to reduce oxygen-related defects.

Thereafter, the process may proceed in accordance with a conventional self-aligned (SA) coplanar thin-film transistor (TFT) process.

According to an example embodiment of the present invention, the method includes depositing a gate insulating layer of SiO₂ with a thickness of 100 nm by plasma-enhanced chemical vapor deposition (PECVD) at 300° C., and depositing a 150 nm-thick Mo layer as the gate electrode by DC sputtering.

The method further includes performing a self-aligned process for n⁺ contacts using NF3 plasma treatment.

According to previous studies, the penetration depth of fluorine (F) introduced into oxide semiconductors by NF₃ plasma treatment is approximately 9 nm.

The doping region is formed in the upper surface region of the active layer. Accordingly, fluorine (F) is not present at the ZrO₂/InGaO interface region.

Subsequently, a 300 nm-thick SiO₂ interlayer is deposited by PECVD for patterning the interlayer using dry etching.

The source and drain electrodes are formed by depositing a 250 nm-thick Mo layer via DC sputtering at 150° C.

Finally, annealing is performed in a vacuum chamber at 250° C. for two hours.

Accordingly, the present invention enables the fabrication of a ferroelectric thin film transistor by adding a ferroelectric layer below the semiconductor layer through an oxide TFT process, wherein the ferroelectric layer is located on the substrate to minimize process-induced effects on the semiconductor layer.

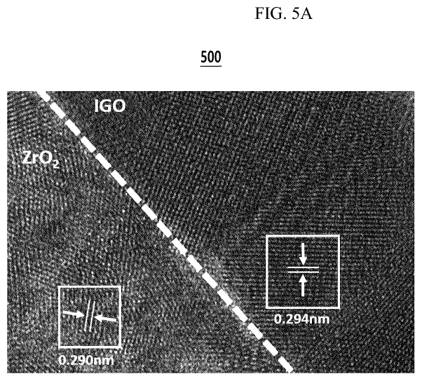

FIGS. 4A to 5C are diagrams illustrating the stacked structure of a ferroelectric thin film transistor according to an example embodiment of the present invention.

FIGS. 4A to 4C illustrate analysis results of the microstructure of a semiconductor layer and a ferroelectric layer in the stacked structure of a ferroelectric thin film transistor, analyzed using transmission electron microscopy (TEM) and energy-dispersive X-ray spectroscopy (EDS) mapping.

FIG. 4A illustrates a TEM image related to the stacked structure of a ferroelectric thin film transistor according to an example embodiment of the present invention.

Referring to FIG. 4A, the image 400 shows a cross-sectional view of the stacked structure of a ferroelectric thin film transistor, clearly illustrating the crystalline structures of the InGaO layer and the ZrO₂ layer.

The thickness of the ZrO₂ layer may be approximately 45 nm, and the thickness of the InGaO layer may be approximately 20 nm.

Ferroelectricity, though generated by a solution-based process, may be observed primarily in the ZrO₂ layer based on its thickness.

FIG. 4B illustrates atomic mapping results for individual elements in the stack composed of In, Ga, Zr, and O, related to the stacked structure of a ferroelectric thin film transistor according to an example embodiment of the present invention.

Referring to FIG. 4B, the image 410 shows EDS (energy-dispersive X-ray spectroscopy) color mapping and depth profiling for evaluating the chemical positions of each element in the ferroelectric device.

FIG. 4C illustrates an EDS depth profile related to the stacked structure of a ferroelectric thin film transistor according to an example embodiment of the present invention.

Referring to FIG. 4C, the graph 420 shows the depth of the InGaO-based semiconductor layer and the depth of the ferroelectric layer corresponding to the ZrO₂ region.

The atomic ratio of In:Ga in the active layer was calculated to be 8:2, which indicates a slightly higher indium enrichment than the precursor solution ratio of 7:3.

The average surface roughness of the ferroelectric layer and the semiconductor layer was measured to be approximately 0.2 nm and 2.1 nm, respectively. Due to the larger grain size, the semiconductor layer exhibits higher surface roughness.

Based on the image 400, image 410, and graph 420, the atomic distribution of In, Ga, Zr, and O in the stacked structure was observed to be uniform, as indicated by color mapping and EDS depth profiles for the individual elements.

FIGS. 5A to 5C illustrate the microstructure of the semiconductor layer and the ferroelectric layer in the stacked structure of a ferroelectric thin film transistor according to an example embodiment of the present invention, analyzed by transmission electron microscopy (TEM) and grazing incidence X-ray diffraction (GIXRD).

FIG. 5A illustrates a TEM image related to the stacked structure of a ferroelectric thin film transistor according to an example embodiment of the present invention.

Referring to FIG. 5A, the image 500 corresponds to a cross-sectional TEM image of the interface between the InGaO semiconductor layer and the ZrO₂ ferroelectric layer.

The semiconductor layer corresponds to the IGO(222) plane with an interplanar spacing (d-spacing) of 0.294 nm, and the ferroelectric layer corresponds to the ZrO₂(111) plane with a d-spacing of 0.290 nm.

Image 500 shows the crystalline structures of both the semiconductor and ferroelectric layers, and ferroelectricity may be observed in the ferroelectric layer, which has a thickness of approximately 45 nm, formed by the solution-based process.

FIG. 5B illustrates fast Fourier transform (FFT) results and corresponding d-spacing values related to the stacked structure of a ferroelectric thin film transistor according to an example embodiment of the present invention.

Referring to FIG. 5B, image 510 represents the ferroelectric layer, while image 511 represents the semiconductor layer.

The d-spacing of the ferroelectric layer is 0.290 nm, and that of the semiconductor layer is 0.294 nm.

Based on the d-spacing value of crystalline ZrO₂, the InGaO layer may exhibit a bixbyite crystal structure.

In crystalline ZrO₂, the d-spacing is approximately 0.290 nm for the orthorhombic (o) phase and approximately 0.254 nm for the tetragonal (t) phase.

Although the measured spacing appears slightly smaller due to the coexistence of the t-phase, the dominant d-spacing indicates a prevailing orthorhombic (o) phase.

The crystal structure observed in the HR-TEM image shows that the ZrO₂ layer exhibits a nanocrystalline (NC) structure with particle sizes of approximately 3 nm and 10 nm, while the InGaO layer exhibits a polycrystalline (PC) structure.

The thermally spray-pyrolyzed ZrO₂ layer is initially in an amorphous phase due to the relatively low deposition temperature of 370° C., but transforms into a crystalline phase during the nitrogen (N₂) annealing process.

During thermal annealing, residual organic solvents evaporate, resulting in a porous structure.

In contrast, InGaO deposited at 390° C. exhibits a PC phase without requiring additional annealing.

Due to the similar d-spacing between o-phase nanocrystalline ZrO₂ and PC-InGaO, the underlying ZrO₂ layer may also serve as a seed layer for crystalline InGaO (c-InGaO) growth.

FIG. 5C shows GIXRD analysis results related to the stacked structure of a ferroelectric thin film transistor according to an example embodiment of the present invention.

Referring to FIG. 5C, the graph 520 illustrates the GIXRD results for the ZrO₂ ferroelectric layer, and the graph 521 illustrates the GIXRD results for the InGaO layer.

The ZrO₂ crystallographic peaks are observed at 2θ =30.45°and 35.38°, with the strongest intensity at 30.45°.

These peaks correspond to the orthorhombic (o)(111) and tetragonal (t)(011) phases, and no peaks associated with the monoclinic (m) phase are observed at 2θ=28.2° or 31.4°.

The InGaO layer shows diffraction peaks at 2θ=31.3°, 36.2°, 52.2°, and 62.0°, corresponding to the (222), (400), (440), and (622) orientations, respectively.

The most intense peak at 31.3° for the (222) orientation indicates the formation of a PC-InGaO layer with an indium oxide-based bixbyite cubic structure.

The position of the GIXRD peaks for InGaO lies between those of the ZrO₂ and InGaO layers in the InGaO/ZrO₂ stack, likely due to a slight mismatch in the interplanar spacing (d-spacing) between the two layers.

Overall, the GIXRD results are consistent with the TEM observations.

The grain size was estimated from the full width at half maximum (FWHM) of the GIXRD peaks, and was approximately 3.69°for ZrO₂ and 0.85° for InGaO.

The orthorhombic phase of the ferroelectric ZrO₂ layer appears to be the dominant phase.

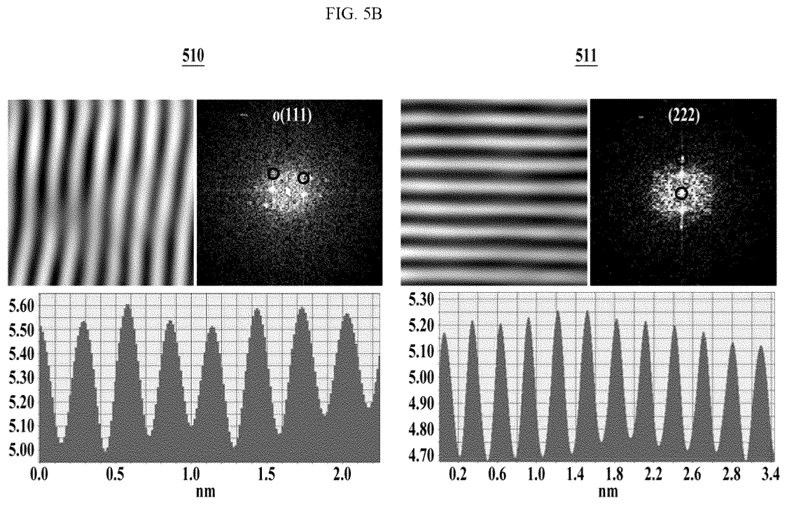

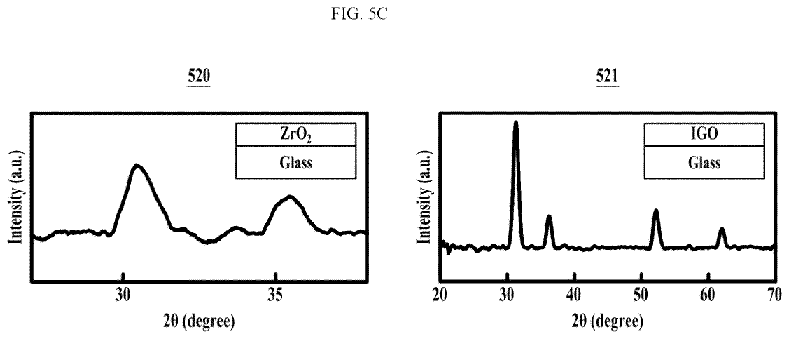

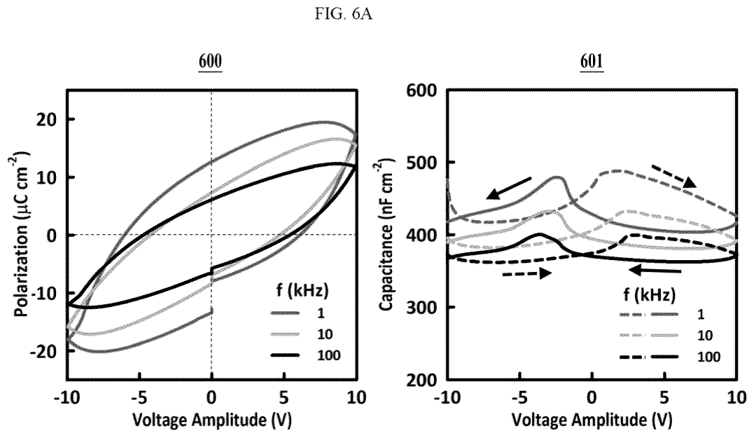

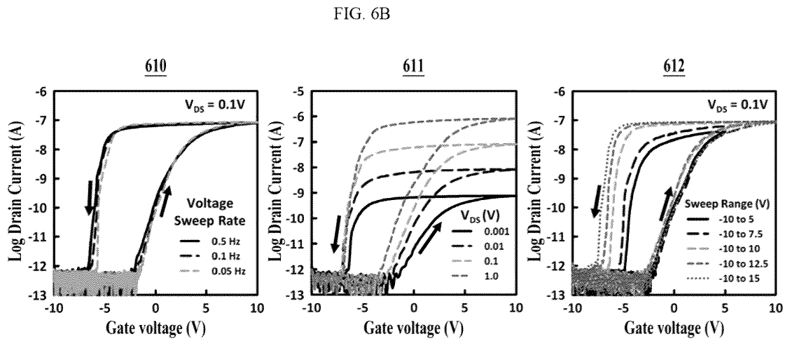

FIGS. 6A and 6B are diagrams illustrating the ferroelectric properties of a ferroelectric thin film transistor according to an example embodiment of the present invention.

FIGS. 6A and 6B illustrate simulation results for the ferroelectric properties of the ferroelectric thin film transistor according to an example embodiment of the present invention.

Referring to FIG. 6A, the graph 600 shows the polarization-voltage (P-V) characteristics of a ferroelectric ZrO₂ capacitor at 1 kHz, 10 kHz, and 100 kHz, and the graph 601 shows the capacitance-voltage (C-V) curve.

As seen in graph 601, the hysteresis loop observed in the P-V measurement and the characteristic “butterfly” curves observed in the C-V curves at various frequencies indicate the ferroelectricity of the ZrO₂ film.

Referring to FIG. 6B, the graphs 610 to 612 illustrate the hysteresis characteristics under various sweep frequencies, drain-source voltages (V_{DS}), and gate-source voltages (V_{GS}).

Graph 610 shows hysteresis loops with sweep rates of 0.05, 0.1, and 0.5 Hz, respectively.

The results show minimal variation with respect to the measurement frequency, indicating that the contribution of ionic differences does not significantly change with frequency.

The effect of ion migration on the counterclockwise hysteresis is negligible.

Graph 611 shows hysteresis curves under various drain-source voltages (V_{DS}) of 0.001 V, 0.01 V, 0.1 V, and 1.0 V, respectively.

As V_{DS} increases from 0.001 V to 1.0 V, the threshold voltage (V_{TH}) during the forward sweep shifts negatively, resulting in a tendency for the memory window (MW) to decrease.

The pinch-off point also tends to shift toward the source side as V_{DS} increases.

This behavior leads to smaller domain switching, which contributes to an increased memory window at lower V_{DS} levels.

Graph 612 shows the variation in sweeping voltage under different program voltages ranging from 5 V to 15 V in 2.5 V steps.

As the program voltage increases, the threshold voltage (V_{TH}) shifts negatively, and the memory window increases, reaching up to 2.3 V.

Only the reverse-sweep V_{TH} is adjusted according to each voltage sweep, indicating stable operation with minimal charge trapping.

To clearly demonstrate ferroelectric behavior, the measurements were performed using applied voltage pulses.

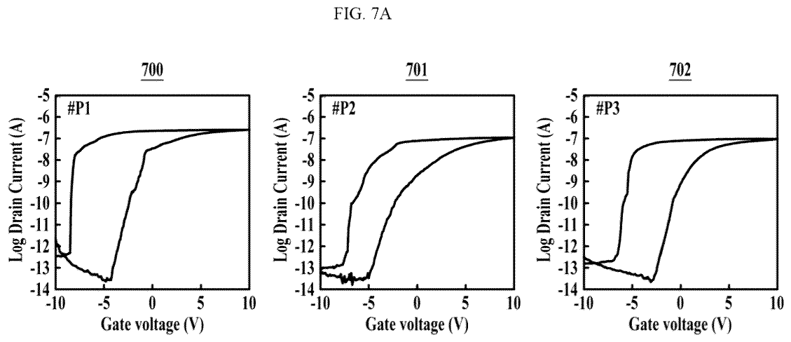

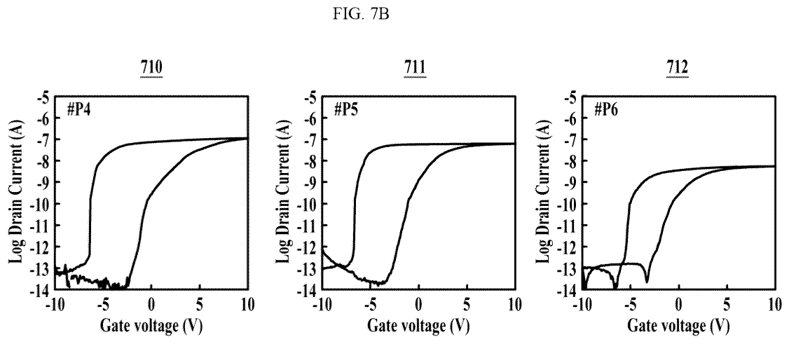

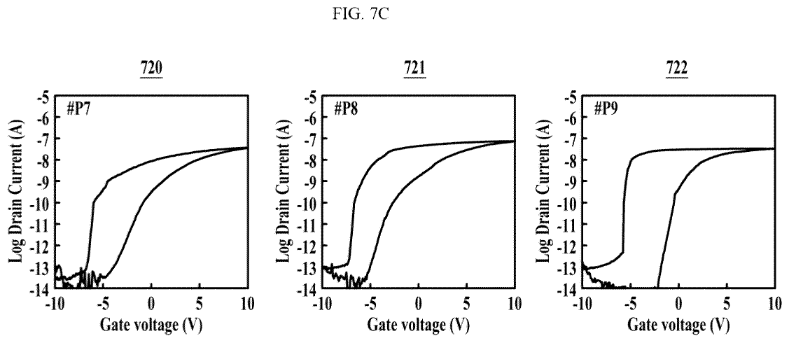

FIGS. 7A to 7C are diagrams illustrating hysteresis curves of a ferroelectric thin film transistor according to an example embodiment of the present invention.

FIGS. 7A to 7C illustrate simulation results for evaluating the average memory window in the ferroelectric thin film transistor according to an example embodiment of the present invention.

Referring to FIG. 7A, graphs 701, 702, and 703 show the measured hysteresis curves at a first position, a second position, and a third position, respectively.

Referring to FIG. 7B, graphs 711, 712, and 713 show the measured hysteresis curves at a third position, a fourth position, and a sixth position, respectively.

Referring to FIG. 7C, graphs 721, 722, and 723 show the measured hysteresis curves at a seventh position, an eighth position, and a ninth position, respectively.

According to graphs 700 through 723, the average memory window based on measurements taken from nine different positions is approximately 5.6 V.

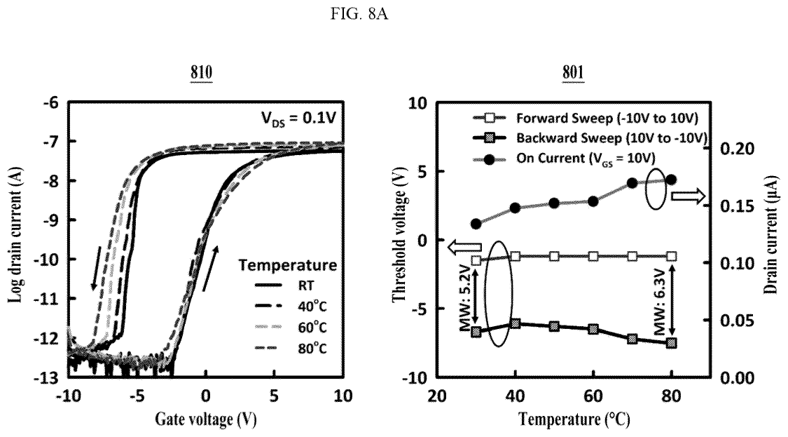

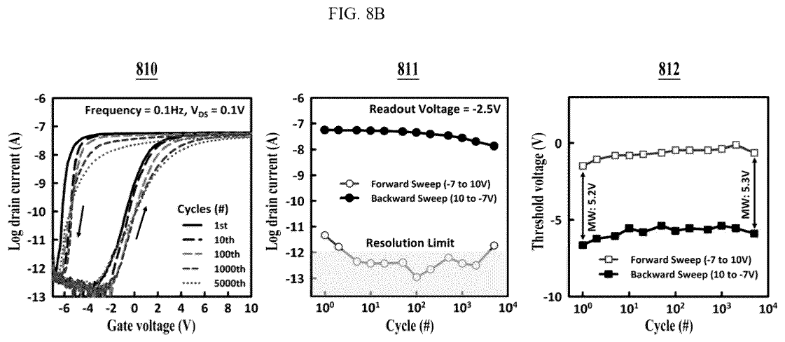

FIGS. 8A and 8B are diagrams illustrating the stability of a ferroelectric thin film transistor according to an example embodiment of the present invention.

FIG. 8A shows hysteresis loops and the temperature dependence of the threshold voltage (V_{TH}) and ON current (I_{ON}) in relation to the thermal stability of the ferroelectric thin film transistor according to an example embodiment of the present invention.

Referring to FIG. 8A, graph 800 shows hysteresis loops measured at temperatures from 20° C. to 80° C. in 20° C. increments, and graph 801 shows the temperature dependence of the threshold voltage (V_{TH}) and ON current (I_{ON}).

The forward threshold voltage (V_{TH}_forward) remains nearly constant with temperature, while the backward threshold voltage (V_{TH}_backward) tends to shift in the negative direction.

Electron trapping at the interface contributes to the positive shift in V_{TH}_forward.

Thus, the shrinkage of the memory window may be attributed to the relaxation of oxygen vacancies in fixed domains, which allows for more switchable dipoles to emerge.

The temperature dependence in oxide semiconductors leads to an increase in carrier concentration with increasing temperature, thereby contributing to increased ON current and a more negative shift in V_{TH}_backward.

To further analyze the device stability, X-ray photoelectron spectroscopy (XPS) was performed on the surface of ZrO₂ films with and without Ar/O₂ plasma treatment.

The analysis was conducted on the surface of the thin film, and O 1s deconvolution revealed binding energies of 530.1±0.1 eV for lattice oxygen (O_{L}), and 532.7±0.1 eV for oxygen vacancies (V_{O}).

For chemisorbed oxygen species (O_{C}), the binding energy was observed around 534.1 eV.

Oxygen-related defect states G4 and G5 showed a significant reduction after Ar/O₂ plasma treatment: the proportion of oxygen vacancies (V_{O}) decreased from 12.7% to 9.2%, and that of chemisorbed oxygen (O_{C}) decreased from 5.8% to 2.3%.

Due to the presence of oxygen-related trap sites at the interface in untreated devices, the current tends to decrease by nearly two orders of magnitude.

Compared to untreated devices, ferroelectric thin film transistors (FE-TFTs) with Ar/O2 plasma treatment exhibit stable performance over temperature variation.

These results indicate that the oxygen vacancy (V_{O}) effect may be significantly reduced by applying Ar/O₂ plasma treatment.

FIG. 8B illustrates additional simulation results related to the stability of the ferroelectric thin film transistor according to an example embodiment of the present invention.

Referring to FIG. 8B, graph 810 shows hysteresis loops as the number of sweep cycles increases up to 5,000.

Graph 811 shows the readout current as a function of the number of cycles at Vreadout=−2.5 V.

Graph 812 shows the extracted threshold voltage (V_{TH}) as a function of the number of cycles, where V_{TH} is obtained from the gate voltage (V_{GS}) at which I_{DS}=W/L×10⁻¹¹ A.

In graph 811, the readout current slightly decreases as the number of endurance cycles increases. However, the current change is less than one order of magnitude, indicating that stable operation is maintained up to 5,000 sweeping cycles.

In graph 812, the memory window (MW) remains stable with a voltage difference of approximately 0.1 V as the number of cycles increases.

The pulse width used for endurance measurement was 10 seconds, which is longer than the pulse durations typically reported in previous studies, thereby confirming enhanced reliability.

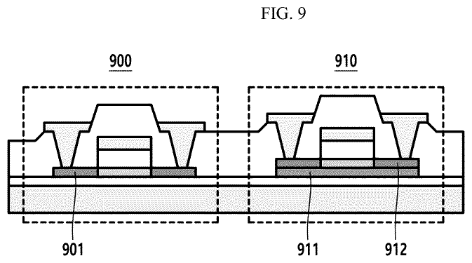

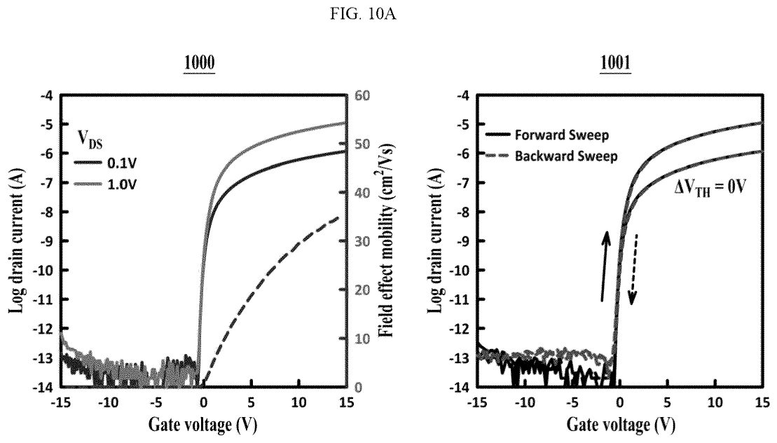

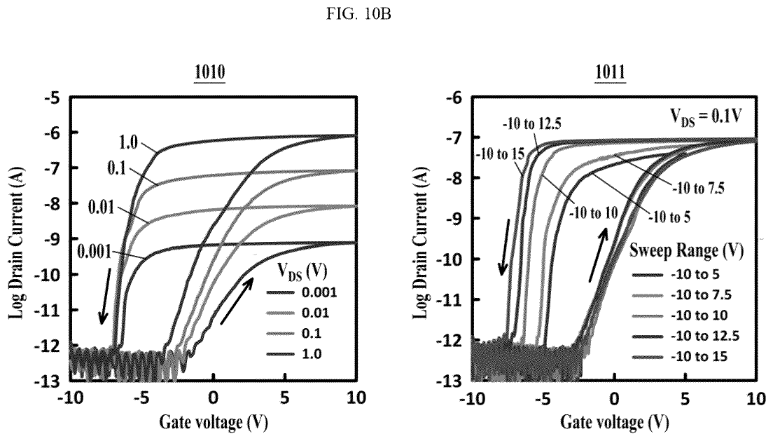

FIGS. 9 to 10B are diagrams illustrating the process compatibility of the ferroelectric thin film transistor according to an example embodiment of the present invention.

Referring to FIG. 9, an oxide switching thin-film transistor structure 900 and a ferroelectric thin-film transistor structure 910 are illustrated.

In structure 900, the semiconductor layer 901 is shown, and in structure 910, the ferroelectric layer 911 is positioned beneath the semiconductor layer 912.

Comparison of structures 900 and 910 demonstrates that the oxide switching thin-film transistor may be implemented by simply omitting the bottom ferroelectric layer, which indicates excellent process compatibility with conventional ferroelectric thin film transistor fabrication methods.

Referring to FIG. 10A, graphs 1000 and 1001 illustrate the electrical characteristics of the oxide switching thin-film transistor.

Graph 1000 shows the transfer curve, and graph 1001 shows the hysteresis curve.

Referring to FIG. 10B, graphs 1010 and 1011 illustrate the characteristics of the ferroelectric thin film transistor.

Graph 1010 shows the transfer curve, and graph 1011 shows the hysteresis curve.

Comparison of FIGS. 10A and 10B indicates that threshold voltage (V_{TH}) tunability is achievable between the oxide switching TFT and the ferroelectric TFT structures.

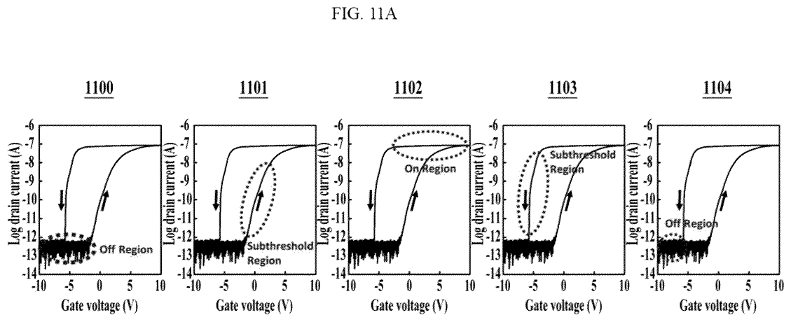

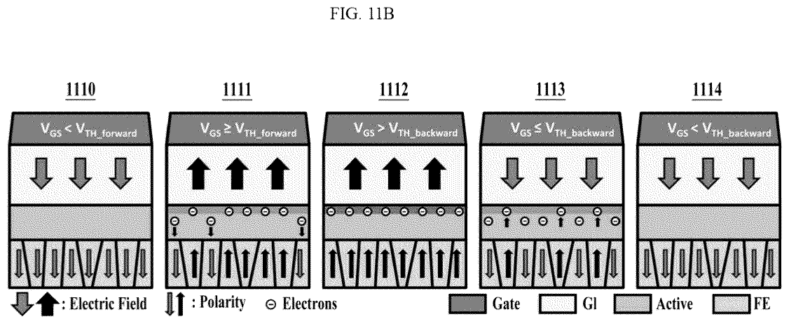

FIGS. 11A and 11B are diagrams illustrating the operation of a ferroelectric thin film transistor according to an example embodiment of the present invention.

FIG. 11A provides data representing hysteresis behavior associated with the operation of the ferroelectric thin film transistor.

FIG. 11B illustrates changes in carrier concentration and polarity in each layer related to the transistor's operation.

Referring to FIG. 11a,
Graph 1100 represents an OFF state, Graph 1101 represents a transition state due to polarity change, Graph 1102 represents an ON state, Graph 1103 represents a polarity change state, and Graph 1104 represents a return to the OFF state.

Referring to FIG. 11b,
Transistor 1110 illustrates the OFF state, Transistor 1111 illustrates a transition state with polarity switching, Transistor 1112 illustrates the ON state, Transistor 1113 illustrates a further polarity switching state, and Transistor 1114 illustrates a return to the OFF state.

Graph 1100 corresponds to transistor 1110, graph 1101 corresponds to transistor 1111, graph 1102 corresponds to transistor 1112, graph 1103 corresponds to transistor 1113, and graph 1104 corresponds to transistor 1114.

Graph 1100 and transistor 1110 represent an OFF state caused by a strong negative electric field and the built-in polarity of the ferroelectric layer.

The semiconductor layer may be determined to be in an OFF state when the gate voltage is less than a forward threshold voltage and the polarity is negative.

Graph 1101 and transistor 1111 illustrate a transition to the ON state due to a change in polarity.

The semiconductor layer may be determined to be in an ON state when the gate voltage is greater than or equal to the forward threshold voltage and the polarity transitions between a negative polarity and a positive polarity.

Graph 1102 and transistor 1112 represent the ON state formed by channel accumulation induced by the embedded polarity of the ferroelectric layer.

The semiconductor layer may be determined to be in an ON state when the gate voltage exceeds the forward threshold voltage and the polarity is positive.

Graph 1103 and transistor 1113 illustrate that the device remains in the ON state due to the formation of a channel by the built-in polarity.

However, the semiconductor layer may be determined to be in an OFF state when the gate voltage is less than or equal to a backward threshold voltage and the polarity transitions between a negative polarity and a positive polarity.

Graph 1104 and transistor 1114 show the OFF state resulting from carrier depletion in the channel and reversed polarity within the ferroelectric layer.

The semiconductor layer may be determined to be in an OFF state when the gate voltage is less than the backward threshold voltage and the polarity is negative.

Accordingly, the present invention provides a ferroelectric thin film transistor and a method of manufacturing the same, in which a ferroelectric layer is positioned below the semiconductor layer and Ar/O₂ plasma treatment is applied to reduce the effect of oxygen vacancies (V_{O}), thereby improving durability, ensuring stable performance under temperature variation, and exhibiting characteristic hysteresis behavior.

The devices described above may be implemented using hardware components, software components, or a combination of hardware and software components.

For example, the devices and components described in the embodiments may be implemented using one or more general-purpose or special-purpose computers, such as a processor, controller, arithmetic logic unit (ALU), digital signal processor (DSP), microcomputer, field programmable array (FPA), programmable logic unit (PLU), microprocessor, or any other device capable of executing and responding to instructions.

The processing unit may execute an operating system (OS) and one or more software applications running on the OS. In response to software execution, the processing unit may access, store, manipulate, process, or generate data.

For ease of understanding, the processing unit may be described as a single unit; however, those skilled in the art will understand that the processing unit may include multiple processing elements and/or different types of processing elements.

For instance, the processing unit may include multiple processors or a combination of a processor and a controller. Other processing configurations, such as parallel processors, are also possible.

The software may include computer programs, code, instructions, or any combination thereof, and may configure or instruct the processing unit to perform desired operations either independently or collectively.

The software and/or data may be embodied permanently or temporarily in any type of machine, component, physical or virtual device, computer-readable medium, or signal wave to be interpreted by or supplied to the processing unit.

The software may also be distributed across network-connected computer systems for distributed storage or execution. The software and data may be stored on one or more computer-readable recording media.

Although the embodiments have been described with reference to limited figures, it will be understood by those skilled in the art that various modifications and variations may be made based on the above descriptions.

For example, the described techniques may be performed in a different order, and/or the described systems, structures, devices, and circuit elements may be combined in different forms, or replaced or substituted with other components or equivalents, while still achieving desired results.

Accordingly, other implementations, modifications, and equivalents of the embodiments described herein are intended to fall within the scope of the following claims.

What is claimed is:

1. A ferroelectric thin film transistor comprising:
a ferroelectric layer formed by depositing a ferroelectric material on a buffer layer provided on a substrate;
a semiconductor layer formed by depositing an oxide on the ferroelectric layer and doping an upper region thereof through plasma treatment;
a gate insulating layer formed by depositing a dielectric material on the semiconductor layer;
a gate electrode formed by depositing a metal material on the gate insulating layer and performing a gate patterning process;
an interlayer formed on the gate electrode and the semiconductor layer; and
a source electrode and a drain electrode formed by patterning the interlayer and depositing a metal material,
wherein the ferroelectric layer is located below the semiconductor layer and exhibits polarity based on ferroelectricity of the ferroelectric material,
wherein the semiconductor layer determines whether a channel is formed in an ON state or an OFF state based on a gate voltage applied through the gate electrode and the polarity.

2. The ferroelectric thin film transistor of claim 1,
wherein the ferroelectric material comprises ZrO₂,
wherein the oxide comprises indium gallium zinc oxide (IGZO),
wherein the metal material comprises Mo, and
wherein the dielectric material comprises SiO₂.

3. The method of claim 2,
wherein the stacked structure of the ferroelectric layer and the semiconductor layer comprises a uniform distribution of In and Ga based on the IGZO and Zr and O based on the ZrO₂.

4. The method of claim 1,
wherein the semiconductor layer is determined to be in an OFF state when:
the gate voltage is less than a forward threshold voltage and the polarity is negative;
the gate voltage is less than or equal to a backward threshold voltage and the polarity transitions between the negative polarity and a positive polarity; or
the gate voltage is less than the backward threshold voltage and the polarity is negative.

5. The method of claim 1,
wherein the semiconductor layer is determined to be in an ON state when:
the gate voltage is greater than or equal to a forward threshold voltage and the polarity transitions between a negative polarity and a positive polarity; or
the gate voltage exceeds the forward threshold voltage and the polarity is positive.

6. A method of manufacturing a ferroelectric thin film transistor, comprising:
forming a ferroelectric layer by depositing a ferroelectric material on a buffer layer provided on a substrate;
forming a semiconductor layer by depositing an oxide on the ferroelectric layer;
forming a gate insulating layer by depositing a dielectric material on the semiconductor layer;
forming a gate electrode by depositing a metal material on the gate insulating layer and performing a gate patterning process;
forming a doped semiconductor layer by doping an upper region of the semiconductor layer through plasma treatment;
forming an interlayer on the gate electrode and the doped semiconductor layer; and
forming a source electrode and a drain electrode by patterning the interlayer and depositing a metal material,
wherein the ferroelectric layer is located below the semiconductor layer and exhibits polarity based on ferroelectricity of the ferroelectric material, and
wherein the semiconductor layer determines whether a channel is formed in an ON state or an OFF state based on a gate voltage applied through the gate electrode and the polarity.

7. The method of claim 6,
wherein the step of forming the ferroelectric layer comprises:
depositing the ferroelectric material as the ferroelectric layer by spray pyrolysis of a precursor solution containing the ferroelectric material; and
forming a crystallized ferroelectric layer by performing plasma treatment using a plasma gas on the deposited ferroelectric layer and annealing the layer in a nitrogen (N2) atmosphere.

8. The method of claim 7,
wherein the ferroelectric material comprises ZrO₂,
wherein the oxide comprises indium gallium zinc oxide (IGZO),
wherein the metal material comprises Mo, and
wherein the dielectric material comprises SiO₂.

9. The method of claim 8,
wherein the stacked structure of the ferroelectric layer and the semiconductor layer comprises a uniform distribution of In and Ga based on the IGZO and Zr and O based on the ZrO₂.

10. The method of claim 6,
wherein the step of forming the doped semiconductor layer by doping an upper region of the semiconductor layer through plasma treatment comprises:
forming the doped semiconductor layer such that an n⁺ doping region is included in the upper region by performing a self-aligned (SA) process for n⁺ contacts through NF3 plasma treatment that introduces fluorine (F) to a predetermined depth.

11. The method of claim 6,
wherein the semiconductor layer is determined to be in an OFF state when:
the gate voltage is less than a forward threshold voltage and the polarity is negative;
the gate voltage is less than or equal to a backward threshold voltage and the polarity transitions between the negative polarity and a positive polarity; or
the gate voltage is less than the backward threshold voltage and the polarity is negative.

12. The method of claim 6,
wherein the semiconductor layer is determined to be in an ON state when:
the gate voltage is greater than or equal to a forward threshold voltage and the polarity transitions between a negative polarity and a positive polarity; or
the gate voltage exceeds the forward threshold voltage and the polarity is positive.
